(19) United States
(12) Patent Application Publication
(10) Pub. No.: US 2024/0274594 A1
(43) Pub. Date: Aug. 15, 2024

(54) STRING DRIVER WITH DEEP TRENCH ISOLATIONS

(71) Applicant: Micron Technology, Inc., Boise, ID (US)

(72) Inventors: Shyam Surthi, Boise, ID (US); Michael A. Smith, Boise, ID (US)

(21) Appl. No.: 18/426,241

(22) Filed: Jan. 29, 2024

Related U.S. Application Data
(60) Provisional application No. 63/444,403, filed on Feb. 9, 2023.

(51) Int. Cl. H01L 27/02; H01L 21/3115; H01L 21/762; H01L 21/768; H01L 21/8238; H01L 25/065; H10B 80/00

(52) U.S. Cl. CPC H01L 27/0207; H01L 21/31155; H01L 21/76224; H01L 21/76816; H01L 21/823864; H01L 25/0657; H10B 80/00; H01L 2225/06541

(57) ABSTRACT

A semiconductor device including a substrate; a plurality of active regions that are disposed on the substrate and that are parallelly aligned; a plurality of first type of trench isolations having a first top critical dimension (CD), each of the plurality of the first type of trench isolations including sidewalls that taper towards one another along a depth direction; and a plurality of second type of trench isolations having a second top CD, the second top CD being larger than the first top CD and each of the plurality of the second type of trench isolations having a flat bottom trench surface.

### CROSS-REFERENCE TO RELATED APPLICATION(S)

The present application claims priority to U.S. Provisional Patent Application No. 63/444,403, filed Feb. 9, 2023, the disclosure of which is incorporated herein by reference in its entirety.

### TECHNICAL FIELD

The present disclosure generally relates to string drivers, and more particularly relates to deep trench isolations in string driver devices for compact device density and/or through wafer interconnects in wafer-on-wafer (WOW) semiconductor packaging.

### BACKGROUND

Advanced semiconductor memory devices assembly generally includes bonding a logic wafer, e.g., a complementary metal-oxide-semiconductor (CMOS) wafer, to a memory array wafer to form a vertically stacking architecture for higher memory storage density and smaller die size. The CMOS wafer may include integrated circuitry with a high density of small components including processor circuits, imager devices, string drivers, and/or high voltage (HV) circuits. In addition, the memory array wafer may include memory arrays including NAND flash memory arrays, dynamic random-access memory (DRAM) arrays, and/or phase change memory (PCM) arrays. The memory arrays can be connected, through the string drivers, to the HV circuits of the CMOS wafer for data signal and control signal transitions. Conventional processes for bonding the CMOS wafer and the memory array wafer include electrically coupling the string drivers of CMOS wafer and the memory arrays of memory wafer through through-wafer interconnects (TWI), which pass through shallow trench isolation regions of the string drivers. In contrast and for conventional memory devices fabrication, the string drivers may be assembled with the memory arrays on a same wafer.

### BRIEF DESCRIPTION OF THE DRAWINGS

FIG. 1A depicts a top-down view of a string driver device layout having deep trench isolations according to embodiments of the present technology.

FIG. 1B depicts a cross-sectional view of the string driver device of FIG. 1A along the A-A′ plane according to embodiments of the present technology.

FIG. 2A depicts a top-down view of a string driver device layout having deep trench isolations according to embodiments of the present technology.

FIGS. 2B and 2C depict cross-sectional views of the string driver device of FIG. 2A along the B-B′ plane according to embodiments of the present technology.

FIGS. 2D and 2E depict cross-sectional views of the string driver device of FIG. 2A along the C-C′ plane according to embodiments of the present technology.

FIG. 3A depicts a top-down view of a string driver device layout having deep trench isolations according to embodiments of the present technology.

FIGS. 3B and 3C depict cross-sectional views of the string driver device of FIG. 3A along the D-D′ plane and E-E′ respectively according to embodiments of the present technology.

FIGS. 4A through 4F illustrate stages of fabricating deep trench isolations in the string driver device according to embodiments of the present technology.

FIG. 5 depicts a top-down view of a string driver device having deep trench isolations according to embodiments of the present technology.

FIG. 6 illustrate a process window of etching deep trenches in the string driver device as functions of top trench critical dimensions and etching angles in accordance with embodiments of the present technology.

FIG. 7 is a flow chart illustrating a method of processing deep trench isolations in string driver devices with through wafer interconnects according to embodiments of the present technology.

FIG. 8 is a flow chart illustrating a method of processing deep trench isolations and ion implanted regions there below in string driver devices according to embodiments of the present technology.

FIG. 9 is a schematic view of a system that includes a semiconductor device configured according to embodiments of the presented technology.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different embodiments designate like or corresponding, but not necessarily identical, elements.

### DETAILED DESCRIPTION

In advanced semiconductor memory devices, such as 3D NAND memory having WOW bonding architecture, the signal transition can be conducted through through-wafer interconnects from the CMOS wafer to memory array. Specifically, for signal transition between string drivers and memory array, the corresponding through-wafer interconnects are configured to pass through shallow trench isolation (STI) regions of string drivers and land on staircase area of the memory array. To continue the scaling of semiconductor memory devices, the dimension of the string driver devices as well as the staircase region of the memory devices need to be further reduced. As a result, there is a need to design a compact layout of the string driver device in order to shrink its footprint and form isolation regions in the string drivers for through-wafer interconnects with reduced pitches. In addition, CMOS devices included string drivers in the CMOS wafer have to accommodate to the memory array wafer contacts for through-wafer interconnects to local memory word lines in a vertical direction.

To address the above-described challenges and others, the present technology introduces a novel string driver device having deep trench isolations that are configured for electrical isolation in the string driver device and/or through-wafer interconnects. The deep trench isolations of the string driver device have a deeper isolation in comparison to conventional STI regions and are pinched off at bottom along a width pitch direction. In addition, the deep trench isolations may completely pass through a substrate of the string driver device, creating socket STIs with a flat bottom surface for processing the through-wafer interconnects there through. In the present technology, the deep trench isolations of string driver device can be fabricated by turning the etch angle and adjusting the trench top opening critical dimension (CD). For example, a deep trench isolation having a depth ranging from 750 nm to 1500 nm can be formed with a trench top opening CD of 50 nm to 100 nm and through adjusting the etch angle to 88 degrees. To form ion implanted regions under the deep trench isolations of string driver devices, the present technology also discloses a two stages etching method including utilizing a sidewall spacer to protect trench surrounding region from implant damages and punching through the spacer at trench bottom surface for trench opening and ion implantation thereafter. Moreover, the present technology includes a design of wider channels of active regions in the string driver devices, through which the trench top opening CD could be effectively reduced to form the pinched off deep trench isolations in the string drivers.

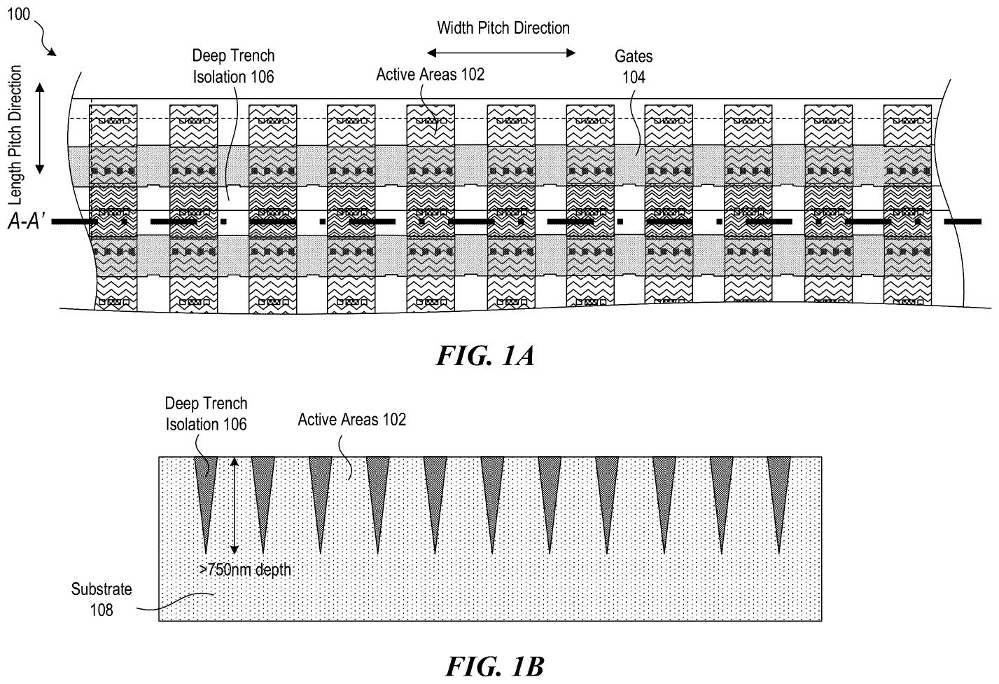

FIG. 1A depicts a top-down view of a layout of string driver device 100 with deep trench isolations 106 according to embodiments of the present technology. The string driver device 100 can be included in a CMOS wafer for WOW bonding for semiconductor device packaging. In this example, the string driver device 100 of FIG. 1A may include a plurality of action areas 102 that are aligned along a length pitch direction and a width pitch direction. Each of the plurality of action areas 102 may include one or more transistors with shared drain regions. In addition, the string driver device 100 may also include a plurality of gates 104 that are aligned perpendicular to the plurality of active areas 102 and disposed above corresponding channels of the plurality of active areas 102. Further, the plurality of active regions 102 are separated by the deep trench isolation 106. As shown in FIG. 1A, the deep trench isolation 106 may surround each of the plurality of active regions 102 for electrical isolation between neighboring string driver devices. In this example, the spacing between edges of neighboring active areas 102 along the length pitch direction can be larger than that along the width pitch direction, in order to prevent punch through during the operations of the string driver device 100.

FIG. 1B depicts a cross-sectional view of the string driver device 100 along the A-A′ plane according to embodiments of the present technology. As shown, each of the plurality of active areas 102 has an island shape and the deep trench isolation 106 is disposed between the neighboring active areas 102. In particular, the deep trench isolation 106 can be formed by etching the substrate 108 through a patterned hard mask layer disposed there above. In this example, corresponding deep trenches with a depth close to or higher than 750 nm can be etched by a proper anisotropic etching technique, e.g., a reactive ion etching (RIE) process. In addition, the deep trench isolation 106 can be filled by electrically non-conductive materials including tetraethyl orthosilicate (TEOS), silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof. In some other examples, the deep trench isolation 106 may be further processed within a shallow trench isolation (STI) region which is formed through etching out the active area islands in the substrate. Specifically, the deep trench isolation 106 may have a trench depth (e.g., close to or higher than 750 nm) deeper than that of the STI regions (e.g., close to 300 nm).

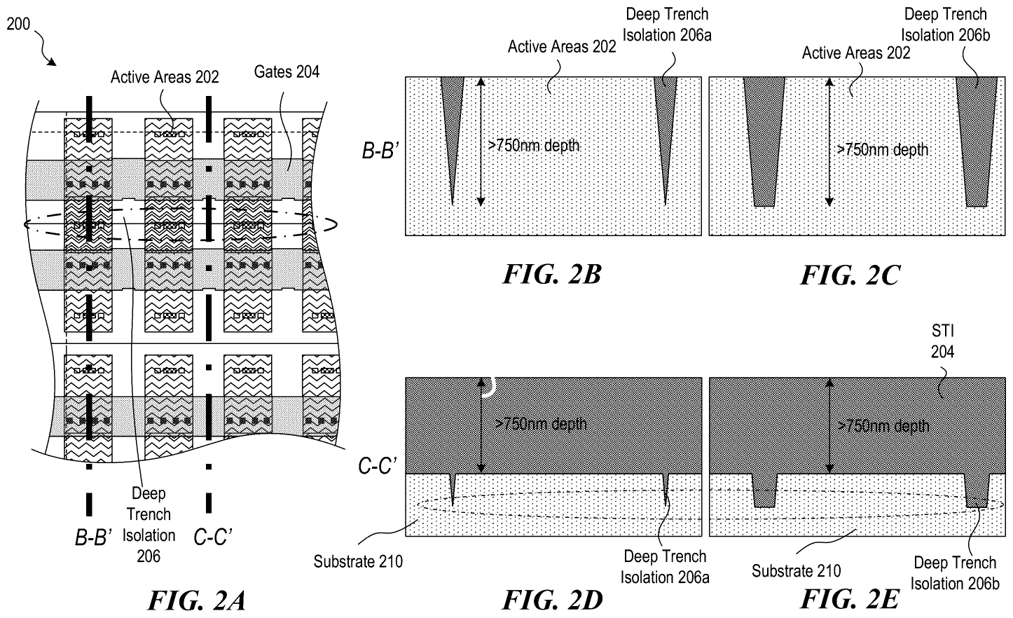

Turning now to FIGS. 2A through 2E which illustrate a string driver device having deep trench isolation and no advanced interconnects are included therein. Specifically, FIGS. 2A through 2E illustrate deep trench isolation 206 along the length pitch direction of the string driver device 200 according to embodiments of the present technology. For example, FIG. 2A shows a zoomed in area of the layout of string driver device 200. FIGS. 2B and 2C show cross-sectional views of the string driver 200 along the B-B′ plane of FIG. 2A which crosses one of the plurality of active areas 202. FIGS. 2D and 2E show cross-sectional views of the string driver 200 along the C-C′ plane of FIG. 2A which crosses the deep trench isolation 202 between neighboring active areas 202.

In the present technology, the deep trench isolation 206 may have various cross-sectional profiles at different regions of the string driver 200. For example, along the B-B′ plane and cross the active regions 202, the deep trench isolation 206a may include sidewalls that taper towards one another along a depth direction. In particularly, the deep trench isolation 206a may be pinched off at its bottom region, as shown in FIG. 2B. In this example, the etching of deep trenches may start from etching a top surface region of the substrate having a relatively smaller top trench CD (e.g., ranging from 50 nm to 100 nm) and/or with a smaller etch angle (e.g., close to or smaller than 87 degrees). The etch angle can be measured from a side wall of the deep trench to an upper surface of corresponding deep trench. Alternatively, the deep trench isolation 206b may be formed with a flat bottom trench surface. Here, the deep trench isolation 206b can be achieved by conducting the etch on the top surface region of the substrate having a relatively larger top trench CD (e.g., ranging from 100 nm to 150 nm) and/or with a larger etch angle (e.g., close to or higher than 88 degrees). Notably, the deep trenches corresponding to the deep trench isolation 206aand 206b can be processed in parallel in an appropriate etch process. In this example, the deep trench isolations 206a and 206b can be disposed close to the edges of the active areas 202 along the length pitch direction.

As described, the deep trench isolation of the present technology can be fabricated within STI regions formed after etching out the active area islands. For example, FIGS. 2D and 2E show the deep trench isolation 206a and 206b that are partially embedded in the STI region 204. As shown, the C-C′ plane is disposed between neighboring active areas 202 and crosses the STI region 204. Compared to the deep trench isolation 206, the STI region is much shallower. In this example, the deep trench isolation 206a and 206b can be formed by etching through the STI region 204 and the substrate 210. Along the C-C′ plane, the deep trench isolation, such as 206a, can be pinched off with a relatively smaller top trench open CD (e.g., ranging from 50 nm to 100 nm), as shown in FIG. 2D. Alternatively, along the C-C′ plane and close the length pitch direction edges of active areas 202, the deep trench isolation 206b may have a relatively larger top trench open CD (e.g., ranging from 100 nm to 150 nm) which causes the flat bottom trench surface, as shown in FIG. 2E.

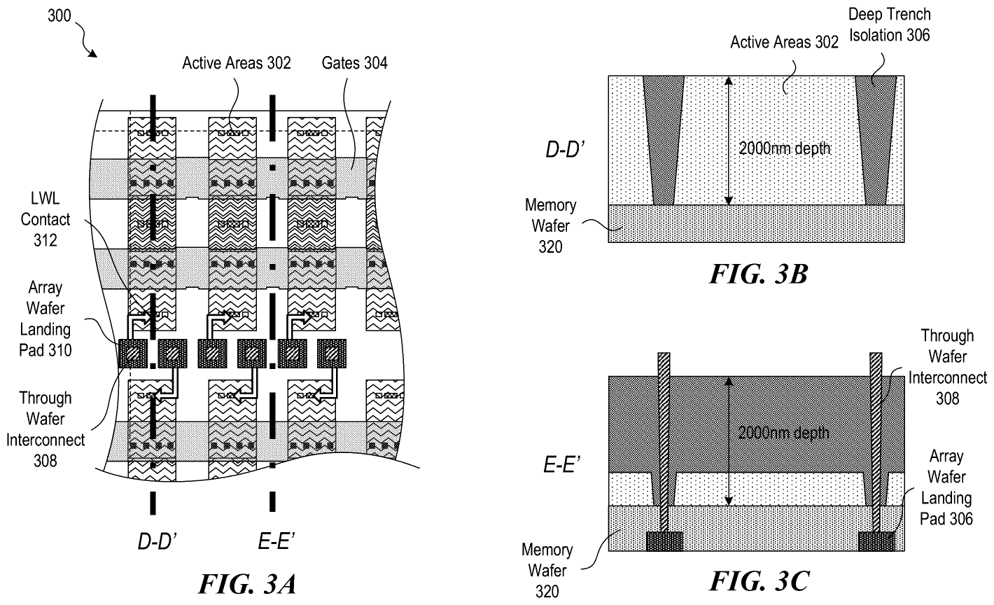

FIGS. 3A through 3C illustrate a string driver device 300 having deep trench isolation 306 and through wafer interconnects 308 passing through corresponding deep trench isolation 306 according to embodiments of the present technology. For example, FIG. 2A shows a layout of the string driver device 300 which includes a plurality of active areas 302 and a plurality of gates that are aligned perpendicular to and disposed above the plurality of active areas 302. The string driver device 300 can be disposed on a CMOS wafer which is bonded to a memory wafer 320 through a WOW bonding technique. As shown in FIG. 3B, the CMOS wafer may be thinned to have a thickness close to 2000 nm and is directly bonded to a frontside surface of the memory wafer 320. Here, the deep trench isolations 306 passes through string driver 300 of the CMOS wafer and are in direct contact to the frontside surface of the memory wafer 320.

In this example, the through wafer interconnects 308 can be disposed next to the length pitch direction end edges of the active areas 302, being close to corresponding local word line (LWL) contacts 312. As described, it is feasible to etch the deep trench corresponding to the deep trench isolation 306 passing through the CMOS wafer, i.e., having a trench thickness close to 2000 nm or above, close to the end edges of the active areas 302. The relatively larger top trench open CD (e.g., ranging from 100 nm to 150 nm) in these regions enables forming the deep trenches with a flat bottom trench surface and a depth of 2000 nm. For electrical isolation purposes, the through wafer interconnects can be further processed to pass through corresponding deep trench isolations 306 and land on corresponding array wafer landing pads 306, as shown in FIG. 3C. FIG. 3A further shows that the through wafer interconnects 308 are aligned to the array wafer landing pads 306, in a top-down view.

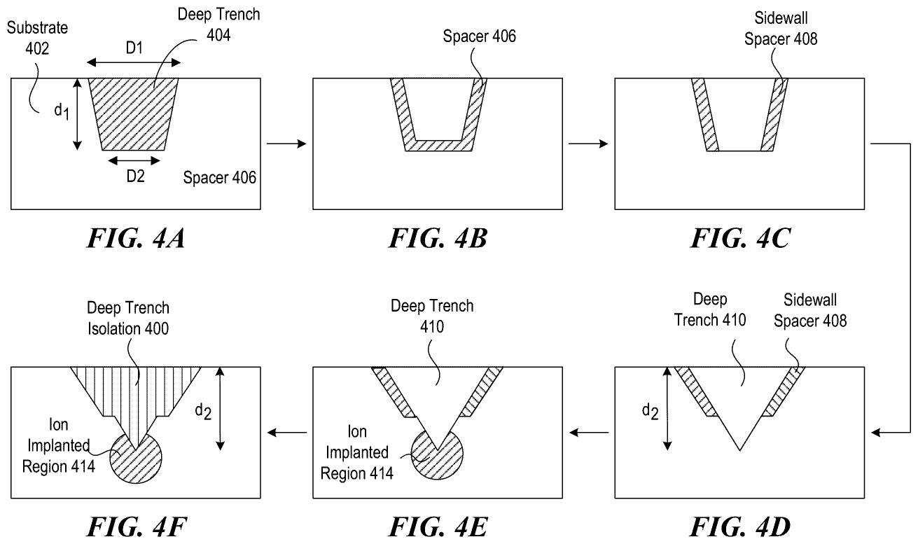

FIGS. 4A through 4F illustrate stages of fabricating deep trench isolation 400 in the string driver device according to embodiments of the present technology. In this example, the deep trench isolation 400 may include sidewalls that taper towards one another along a depth direction. In particular, the deep trench isolation 400 may be pinched off at the trench bottom portion and an ion implanted region 414 can be disposed underneath the trench bottom region of the deep trench isolation 400. To assist the illustration, FIGS. 4A through 4F are zoomed in views collected from the trench bottom region. As shown in FIG. 4A, a first etching can be conducted on the substrate 402 to form a first deep trench 404. The substrate 402 can be made of a P type lightly doped single crystal silicon. In addition, an anisotropic etching technique, e.g., a reactive ion etching (RIE) process, can be utilized in this stage to etch the first deep trench 404 having a flat trench bottom surface. This first etching may be performed through a top open space with a critical dimension (CD) D1 on a frontside surface of the substrate 402. In this example, the top open CD may be ranging from 50 nm to 100 nm. Moreover, in this first etching, a proper substrate etch angle, e.g., from 86 degrees to 89 degrees, is selected in the first etching process to avoid pinch off at the trench bottom region and form the flat trench bottom surface. The etch angle can be measured from a sidewall of the deep trench to an upper surface of corresponding deep trench isolation. A third depth D1 measured vertically from the frontside surface of substrate 402 and the flat bottom surface of the deep trench 404 can be ranging from 750 nm to 1500 nm. Further, the flat bottom surface may have a CD of D2 ranging from 10 nm to 50 nm.

In a next step, as shown in FIG. 4B, a sacrificial spacer 406 can be deposited on the sidewall and bottom surface of the deep trench 404. The spacer 406 may be an insulating dielectric material, e.g., silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof. Further, the spacer 406 may have an etching selectivity to that of the substrate 402, meaning the substrate 406 can be selectively etched without removing the sacrificial spacer 406. In this example, the spacer 406 can be conformally deposited inside the deep trench 404 by any appropriate techniques including, chemical vapor deposition (CVD), physical vapor deposition (PVD), atomic layer deposition (ALD), or gas cluster ion beam (GCIB) deposition. Here, the spacer 406 may have a thickness ranging from 5 nm to 20 nm.

In a next step, the spacer 406 deposited on the trench bottom surface of the deep trench 404 can be removed as shown in FIG. 4C. This can be done through a directional etch process, e.g., a RIE process or a remote plasma etch process, to punch etch the bottom portion of the spacer 406. After this etch, sidewall spacer 408 will be left over the internal sidewall of the deep trench 404.

Once the bottom portion of the spacer 406 is removed, a secondary etch can be conducted through the deep trench 404 and into the substrate 402. As shown in FIG. 4D, this secondary etch can form a pinched off region below the flat bottom surface of the original deep trench 404. An appropriate etching process, e.g., a RIE process, can be used here to form the deep trench 410 having the bottom pinched off region. Various knobs including the trench 404 bottom CD D2 and etching angle of the secondary etch can be tuned to form the pinched off region. Notably, the secondary etch will not deform the sidewall of the deep trench 404 as it is covered by the sidewall spacer 408, which is resistant to the secondary etch on the substrate 402. In particular, the sidewall spacer 408 may have an etch selectivity to the substrate 402 close to or higher than 100:1.

In a next step, as shown in FIG. 4E, an ion implanted region 414 can be formed close to the deep trench 410 pinched off region and in the substrate 402. For a P type lightly doped substrate 402, the ion implanted region 306 may be formed by implanting P type dopant materials such as Boron and/or Gallium through the deep trench 410. Because the sidewall of the deep trench 404 is protected by the spacer 408, the dopant materials will be implanted into the substrate 402 through the pinched off region of the deep trench 410. In this example, the ion implantation in the upper sidewall portion of the deep trench 410 can be greatly prohibited.

In a next step, the sidewall spacer 408 can be removed from the deep trench 410 as shown in FIG. 4F. This sidewall spacer material removal can be done through a spacer etching process including a dry etch process or a wets etch process. The selective spacer etching process can selectively remove the sidewall spacer 408, without etching the exposed substrate 402 at the bottom pinched off region of the deep trench 410. Here, the deep trench 410 may have a final first depth d2, measured from the frontside surface of the substrate 402 to the pinched off bottom region, ranging from 750 nm to 1500 nm. As shown in FIG. 4F, the sidewall of the deep trench 400 is segmented, being discontinuous close to the pinched off trench bottom region. Further, dielectric materials such as silicon oxide can be deposited into the deep trench 410 to form the deep trench isolation 400. The frontside surface of the deep trench isolation 400 may be planarized by a chemical-mechanical polishing (CMP) process.

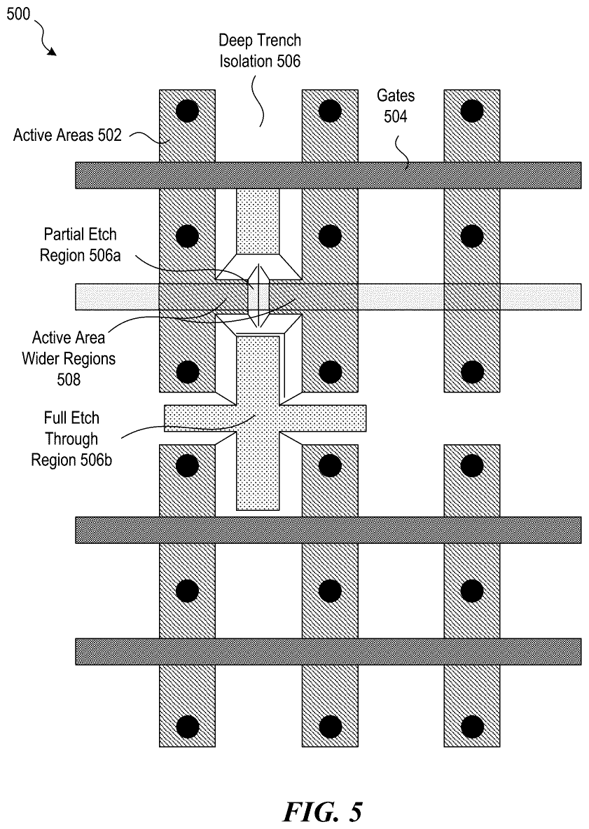

In the present technology, complete isolations can be formed between certain parts of the string driver devices. In addition, pinched off deep trench isolations can also be formed between channels of neighboring parallelly aligned action areas of string driver devices through a selectively wider channel design. For example, FIG. 5 depicts a top-down view of a string driver device 500 with deep trench isolations 506 according to embodiments of the present technology. The deep trench isolations 506 in this example include partial etch region 506a and full etch through region 506b. Specifically, the deep trenches are pinched off at the partial etch region 506a and completely etch through the substrate (not shown) of the string driver device 500.

As described, the string driver devices such as the string driver device 500 include a plurality of active areas 502 that are parallelly aligned. In general, each of the plurality of active areas 502 are etched from the substrate into parallelly aligned islands. The active area islands are isolated by the dielectric materials disposed therebetween for electrical isolation. Deep trench isolation 506 can be further fabricated between the neighboring active areas with a deeper trench depth, e.g., from 750 nm to 1500 nm, to enhance the electrical isolation between neighboring string driver devices. In this example, each of the plurality of active areas 502 may include one or more channels, above which the gates 504 are aligned in a perpendicular direction.

In this example, the string driver devices may have regions with various open CD for forming trenches of the deep trench isolation 506. For example, the fully etch through region 506 disposed close the longitude edges of the action regions 502 may have a larger open space compared to the opening region between the channels of neighboring aligned active regions along its width direction. Further, as shown in FIG. 5, each of the plurality of active regions may include the active area wider regions 508. The active area wider regions 508 may have a large width compared to other regions of corresponding active area 502, causing a smaller open CD therebetween. The small open CD close to the active area wider regions 508, in turn, could lead to a pinched off trench during a deep trench etch process, as shown in FIG. 5. In meanwhile, trenches that are completely etched through the substrate can be formed in the full etch through region 506b, wherein the top trench open CD is larger than that of the partial etch region 506a. In this example, the substrate of the string driver devices may be close to 2000 nm. Moreover, the trench top open CD may be close to 50 nm and 150 nm for the partial etch region 506a and the full etch through region 506b, respectively. This configuration enables string drivers body/well control through a continuous body zone, e.g., under the partial etch region 506a. In addition, the spacing between edges of active regions along their length direction is preferred to be larger than the spacing between active regions along their width direction. This helps to minimize potential drain-to-drain punch through during the operation of string driver devices by forming a deeper trench isolation, through the larger spacings between the edges of active regions along their length direction.

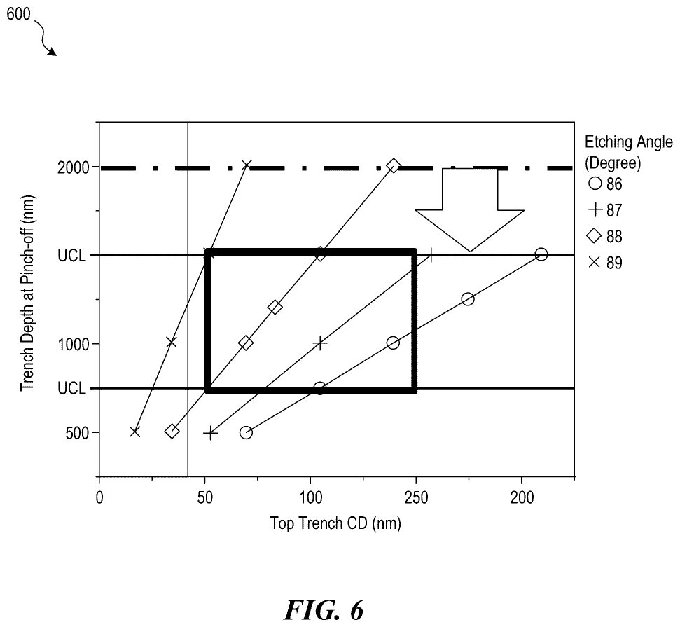

The present technology may rely on precise control in the deep trench etching process to achieve desired deep trench isolation profiles described from FIGS. 1A through 5. For example, FIG. 6 illustrate the trench depth at pinch-off as functions of the top trench CD and Silicon etching angle. Specifically, a preferrable operation regime for the etching process is identified for forming the deep trench isolations in the string driver device of the present technology. As described, the deep trenches can be etched by the RIE process, which is a combination of both chemical reactions and physical removals. Here, the chemical reactions in the RIE process could consume the silicon substrate and the physical removal operations can remove residue materials from the deep trenches by momentum transfer. The RIE process can be chosen in the present technology because it has advantages in process control, a high etching rate, high etch selectivity and cleanliness.

As shown in FIG. 6, the trench depth increases as enlarging the top trench CD. Specifically, the trench depth and top trench CD appears to be in a linear relationship. Here, a large top trench CD could help delivering more etch chemicals into the substrate and assisting removal of etch residues from the deep trench region. Because the minimum isolation distance between action regions in the string driver device is close to 40 nm (e.g., between neighboring parallelly aligned action area islands), the top trench CD for the etch process in the present technology is preferrable to be larger than 50 nm. The plotting of trench depths in FIG. 6 are also distinguishable by the silicon etch angles. Particularly, FIG. 6 includes 4 curves each representing a trench depth as a function of top trench CD with a specific silicon etch angle ranging from 86 degrees to 89 degrees. It could be found that a higher etch angle contributes to a steeper curve of the trench depth, meaning a higher etch angle could cause a deeper trench depth at a same top trench CD.

In the present technology, the string driver deep trench isolation may have a depth ranging from 750 nm to 1500 nm, specifically between the string driver active area islands. This deep trench depth specification could ensure there is continuous body/well connections between neighboring string driver devices in the present technology. To meet this specification, the operating regime of the RIE process can be configured to have the top trench CD ranging from 50 nm to 150 nm, with a silicon etch angle close to 87 degrees or 88 degrees, as shown in FIG. 6. For advanced through wafer interconnects in WOW packaging, the etch process could also provide a process margin in achieving a trench depth of 2000 nm for a through wafer insulation.

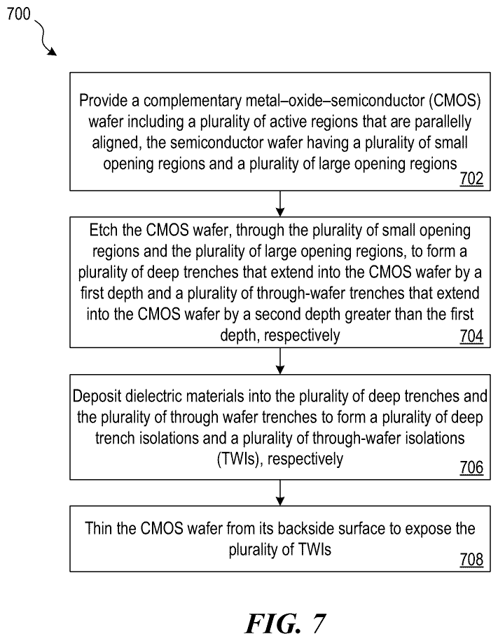

FIG. 7 is a flow chart illustrating a method 700 for processing deep trench isolations in string driver devices with through wafer interconnects according to embodiments of the present technology. The method 700 includes providing a complementary metal-oxide-semiconductor (CMOS) wafer including a plurality of active regions that are parallelly aligned, the semiconductor wafer having a plurality of small opening regions and a plurality of large opening regions, at 702. For example, a CMOS wafer including the string driver device 500 can be provided for the processing of deep trench isolation 506, as shown in FIG. 5. There are a plurality of small opening regions correspond to the partial etch region 506a and disposed between the active area wider regions 508 of the active areas 502. The string driver device 500 also includes a plurality of large opening regions correspond to the full etch through region 506b and disposed close to the end edges of the plurality of active areas 502.

In addition, the method 700 includes etching the CMOS wafer, through the plurality of small opening regions and the plurality of large opening regions, to form a plurality of deep trenches that extend into the CMOS wafer by a first depth and a plurality of through-wafer trenches that extend into the CMOS wafer by a second depth greater than the first depth, respectively, at 704. For example, an appropriate etching process such as a RIE process can be used to etch the deep trenches for the deep trench isolation 506 on the string driver device 500. Shallower trenches such as the partial etch region 506a can be formed with a depth ranging from 750 nm to 1500 nm between the parallelly aligned active areas 502. Moreover, completely etch through trenches such as deep trenches having a flat bottom surface and a depth close to 2000 nm can be formed close to the end edges of the active areas 502.

Further, the method 700 includes depositing dielectric materials into the plurality of deep trenches and the plurality of through wafer trenches to form a plurality of deep trench isolations and a plurality of through-wafer isolations (TWIs), respectively, at 706. For example, dielectric materials such as silicon oxide can be deposited into the deep trench isolation 506 to form bottom pinched off isolation and complete through wafer isolation in the partial etch region 506a and the full etch through region 506b, respectively.

Lastly, the method 700 includes thinning the CMOS wafer from its backside surface to expose the plurality of TWIs, at 708. For example, the string driver device 500 can be thinned from its backside, using a suitable technique such as wafer back grinding to remove the bulk of excess substrate/wafer thickness. Specifically, the CMOS wafer can be thinned to a thickness close to 2000 nm so as to expose the full etch through region 506b, as shown in FIG. 5.

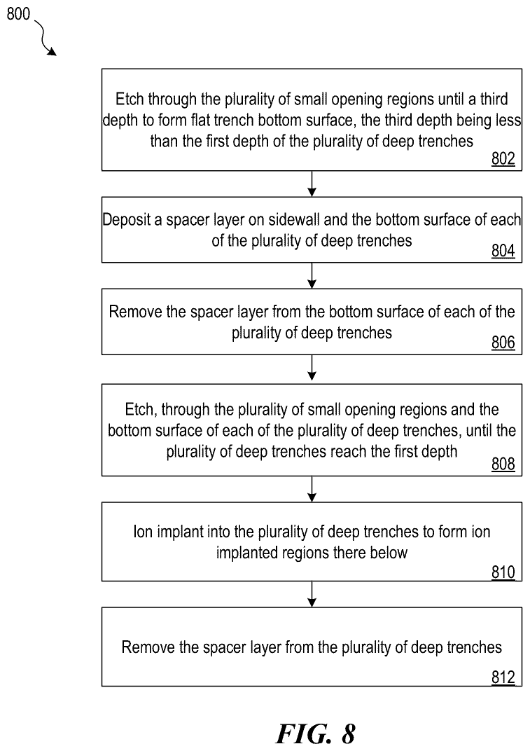

Turning to FIG. 8 which is a flow chart illustrating a method 800 of processing deep trench isolations and ion implanted regions there below in string driver devices according to embodiments of the present technology. The method 800 includes etching through the plurality of small opening regions until a third depth to form flat trench bottom surface, the third depth being less than the first depth of the plurality of deep trenches, at 802. For example, an etch process can be conducted on a small open regions (e.g., having a CD ranging from 50 nm to 100 nm) of the string driver wafer surface to form the deep trench 404. This etch process can be controlled to form a third depth d1 and a flat bottom trench surface of the deep trench 404, as shown in FIG. 4A. In addition, the third depth d1 can be less than a first depth d2.

The method 800 also includes depositing a spacer layer on sidewall and the bottom surface of each of the plurality of deep trenches, at 804. For example and as shown in FIG. 4B, spacer 406 can be conformally deposited on the internal sidewall and bottom flat surface of the deep trench 404 with a thickness ranging from 5 nm to 20 nm.

In addition, the method 800 includes removing the spacer layer from the bottom surface of each of the plurality of deep trenches, at 806. For example, a directional etch process such as a RIE process can be used to remove the spacer 406 from the bottom flat surface of the deep trench 404. As shown in FIG. 4C, the sidewall spacer 408 is maintained after the bottom surface spacer removing process and the flat bottom surface of the deep trench 404 is exposed.

The method 800 further includes etching, through the plurality of small opening regions and the bottom surface of each of the plurality of deep trenches, until the plurality of deep trenches reach the first depth, at 808. For example, a secondary etch process can be conducted through the exposed flat bottom surface of the deep trench 404 to etch into the substrate 402. The secondary etch will be pinched off and form the deep trench 410 with a target first trench depth of d2. As shown in FIG. 4D, the substrate 402 close to the sidewall of deep trench 410 is not eroded due to the protection of sidewall spacer 408.

In addition, the method 800 includes ion implanting into the plurality of deep trenches to form ion implanted regions there below, at 810. For example, a P type dopant material can be implanted through the pinched off bottom region of the deep trench 410 into the substrate 410. This ion implantation process can generate a P type doped region below the Deep trench 410, as shown in FIG. 4E.

Lastly, the method 800 includes removing the spacer layer from the plurality of deep trenches, at 812. For example, dielectric materials including silicon oxide can be deposited into the deep trench 400 after the ion implantation step. The frontside surface of the string driver wafer may be planarized to complete the deep trench isolation 400 shown in FIG. 4F.

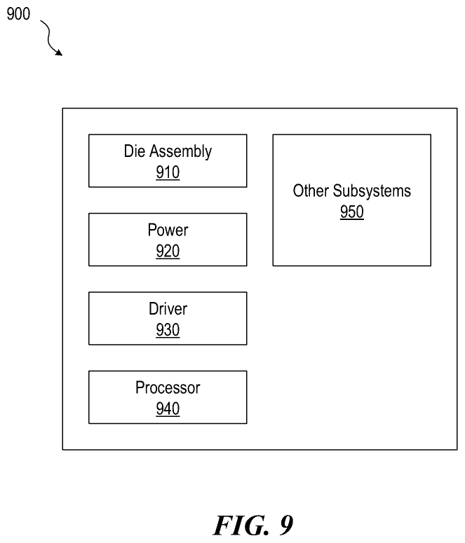

Any one of the semiconductor structures described above with reference to FIGS. 1A-5 can be incorporated into any of a myriad of larger and/or more complex systems, a representative example of which is system 900 shown schematically in FIG. 9. The system 900 can include a semiconductor device 910, a power source 920, a driver 930, a processor 940, and/or other subsystems or components 950. The semiconductor device 910 can include features generally similar to those of the semiconductor devices described above and can therefore include string drivers with deep trench isolation described in the present technology. The resulting system 900 can perform any of a wide variety of functions, such as memory storage, data processing, and/or other suitable functions. Accordingly, representative systems 900 can include, without limitation, hand-held devices (e.g., mobile phones, tablets, digital readers, and digital audio players), computers, and appliances. Components of the system 900 may be housed in a single unit or distributed over multiple, interconnected units (e.g., through a communications network). The components of the system 900 can also include remote devices and any of a wide variety of computer-readable media.

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In accordance with one aspect of the present disclosure, the semiconductor devices illustrated above could be memory dice, such as dynamic random access memory (DRAM) dice, NOT-AND (NAND) memory dice, NOT-OR (NOR) memory dice, magnetic random access memory (MRAM) dice, phase change memory (PCM) dice, ferroelectric random access memory (FeRAM) dice, static random access memory (SRAM) dice, or the like. In an embodiment in which multiple dice are provided in a single assembly, the semiconductor devices could be memory dice of a same kind (e.g., both NAND, both DRAM, etc.) or memory dice of different kinds (e.g., one DRAM and one NAND, etc.). In accordance with another aspect of the present disclosure, the semiconductor dice of the assemblies illustrated and described above could be logic dice (e.g., controller dice, processor dice, etc.), or a mix of logic and memory dice (e.g., a memory controller die and a memory die controlled thereby).

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “top,” “bottom,” “over,” “under,” “above,” and “below” can refer to relative directions or positions of features in the semiconductor devices in view of the orientation shown in the Figures. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device, comprising:
a substrate;
a plurality of active regions that are disposed on the substrate and that are parallelly aligned;
a plurality of first type of trench isolations having a first top critical dimension (CD), each of the plurality of the first type of trench isolations including sidewalls that taper towards one another along a depth direction; and
a plurality of second type of trench isolations having a second top CD, the second top CD being larger than the first top CD and each of the plurality of the second type of trench isolations having a flat bottom trench surface.

2. The semiconductor device of claim 1, wherein the plurality of first type of trench isolations are disposed adjacent to channel regions of each of the plurality of active regions, and the plurality of second type of trench isolations are disposed adjacent to edges of each of the plurality of active regions.

3. The semiconductor device of claim 2, wherein the plurality of first type of trench isolations and the plurality of second type of trench isolations each has a sidewall slope angle that is measured from an upper surface of corresponding trench isolation and that ranges from 85 degrees to 90 degrees.

4. The semiconductor device of claim 3, wherein the first top CD of the plurality of first type of trench isolations ranges from 50 nm to 100 nm, the second top CD of the plurality of second type of trench isolations ranges from 50 nm to 300 nm, and the plurality of first type of trench isolations and the plurality of second type of trench isolations have a trench depth ranging from 750 nm to 2000 nm.

5. The semiconductor device of claim 2, wherein the plurality of second type of trench isolations pass through the substrate.

6. The semiconductor device of claim 5, further comprising a plurality of through-wafer interconnects passing through corresponding second type of trench isolations, the plurality of through-wafer interconnects being connected to corresponding local word line (LWL) contacts disposed above the plurality of active regions.

7. The semiconductor device of claim 6, wherein the semiconductor device is bonded to a memory module, and wherein the plurality of through-wafer interconnects are connected to corresponding array wafer landing pads of the memory module, respectively.

8. The semiconductor device of claim 1, further comprising a plurality of ion implanted regions that are disposed under corresponding first type trench isolations, wherein the sidewall of the first type trench isolations is segmented.

9. A semiconductor device, comprising:
a complementary metal-oxide-semiconductor (CMOS) device including a substrate and a plurality of string driver devices, each of the plurality of string driver devices including:
a plurality of active regions that are disposed on the substrate and that are parallelly aligned, each of the plurality of active regions includes one or more channel regions,
a plurality of deep trench isolations that are disposed adjacent to the channel regions of the plurality of active regions, each of the plurality of the deep trench isolations including sidewalls that taper towards one another along a depth direction, and
a plurality of through-wafer isolations (TWIs) that are disposed adjacent to corresponding edges of the plurality of active regions, and
a memory device including one or more memory arrays;
wherein the CMOS device is bonded to the memory device, having the plurality of TWIs of the CMOS device connected to the memory device.

10. The semiconductor device of claim 9, wherein the plurality of TWIs have a flat bottom trench surface and pass through the substrate.

11. The semiconductor device of claim 10, wherein the plurality of first type of trench isolations and the plurality of second type of trench isolations each has a sidewall slope angle that is measured from an upper surface of corresponding trench isolation and that ranges from 85 degrees to 90 degrees.

12. The semiconductor device of claim 11, wherein each of the plurality of deep trench isolations has a first top critical dimension (CD) ranging from 50 nm to 100 nm, each of the TWIs has a second top CD ranging from 50 nm to 300 nm, the second top CD being larger than the first top CD, and the plurality of deep trench isolations and the plurality of TWIs have a trench depth ranging from 750 nm to 2000 nm.

13. The semiconductor device of claim 10, further comprising a plurality of through-wafer interconnects passing through corresponding TWI, the plurality of through-wafer interconnects being connected to corresponding local word line (LWL) contacts disposed above the plurality of active regions of the CMOS device, wherein the plurality of through-wafer interconnects are connected, through corresponding TWIs, to corresponding memory arrays of the memory device.

14. The semiconductor device of claim 9, wherein each of the plurality of active regions is wider under corresponding channels included therein, compared to its remaining region.

15. A method of forming a string driver device, comprising:
providing a complementary metal-oxide-semiconductor (CMOS) wafer including a plurality of active regions that are parallelly aligned, the semiconductor wafer having a plurality of small opening regions and a plurality of large opening regions on its frontside surface;
etching the CMOS wafer, through the plurality of small opening regions and the plurality of large opening regions, to form a plurality of deep trenches that extend into the CMOS wafer by a first depth and a plurality of through-wafer trenches that extend into the CMOS wafer by a second depth greater than the first depth, respectively;
depositing dielectric materials into the plurality of deep trenches and the plurality of through wafer trenches to form a plurality of deep trench isolations and a plurality of through-wafer isolations (TWIs), respectively; and
thinning the CMOS wafer from its backside surface to expose the plurality of TWIs.

16. The method of forming the string driver device of claim 15, wherein each of the plurality of deep trenches includes sidewalls that taper towards one another along a depth direction, and each of the plurality of the through wafer trenches has a flat bottom trench surface.

17. The method of forming the string driver device of claim 15, wherein the etching of the CMOS wafer to form a plurality of deep trenches includes:
etching through the plurality of small opening regions until a third depth to form flat trench bottom surface, the third depth being less than the first depth of the plurality of deep trenches,
depositing a spacer layer on sidewall and the bottom surface of each of the plurality of deep trenches,
removing the spacer layer from the bottom surface of each of the plurality of deep trenches,
etching, through the plurality of small opening regions and the bottom surface of each of the plurality of deep trenches, until the plurality of deep trenches reach the first depth target,
ion implanting into the plurality of deep trenches to form ion implanted regions there below, and
removing the spacer layer from the plurality of deep trenches.

18. The method of forming the string driver device of claim 17, further comprising bonding the CMOS wafer to a memory wafer which includes one or more memory arrays.

19. The method of forming the string driver device of claim 18, further comprising forming a plurality of through-wafer interconnects that pass through corresponding TWIs, each of the plurality of through-wafer interconnects connecting corresponding active region of the CMOS wafer to corresponding memory array of the memory wafer.

20. The method of forming the string driver device of claim 15, wherein etching the CMOS wafer to form the plurality of deep trenches and the plurality of through wafer trenches includes turning an etch angle from 85 degrees to 90 degrees.
